(19) United States
(12) Patent Application Publication
(10) Pub. No.: US 2021/0202300 A1
(43) Pub. Date: Jul. 1, 2021

(54) FABRICATING METAL-OXIDE SEMICONDUCTOR DEVICE USING A POST-LINEAR-ANNEAL OPERATION

(71) Applicant: Cloudwalk Technology Corp., Santa Clara, CA (US)

(72) Inventor: Xi ZHOU, Santa Clara (US)

(73) Assignee: Cloudwalk Technology Corp., Santa Clara, CA (US)

(21) Appl. No.: 16/729,519

(22) Filed: Dec. 30, 2019

(51) Int. Cl. H01L 21/762; C23C 16/24; H01L 21/302; H01L 21/02

(52) U.S. Cl. CPC H01L 21/76229; H01L 21/0217; H01L 21/302; C23C 16/24

(57) ABSTRACT

In accordance with embodiments of the present disclosure, a method for fabricating a Metal-Oxide Semiconductor (MOS) device may include: depositing a silicon-nitride (SiN) layer above a substrate surface of a silicon wafer; etching one or more trenches on the silicon wafer; performing a high-temperature post-liner-anneal process on the silicon wafer to reduce stress from the etched SiN layer to the silicon wafer; and filling the one or more trenches with oxide isolation material. The high-temperature post-liner-anneal process may reduce the dependence of the saturation current of the MOS device on the channel width.

### BACKGROUND

### Field of Disclosure

The present disclosure relates to the fabrication of integrated circuit devices, and in particular, to a method for fabricating a Metal-Oxide Semiconductor (MOS) device using a post-linear-anneal operation.

### Description of Related Arts

Unless otherwise indicated herein, the approaches described in this section are not prior art to the claims in this application and are not admitted to be prior art by inclusion in this section.

Shallow Trench Isolation (STI) has been widely used in Metal-Oxide-Semiconductor (MOS) devices with a Critical Dimension (CD) below 0.25 um. In a conventional STI process, a silicon wafer may undergo many complicated operations to fabricate the STI structure. During these operations, stress may generally be accumulated in the active region of the silicon wafer, which may affect the electrical performance of the fabricated MOS devices.

The STI stress is mainly caused by the curvature of the silicon wafer before a trench isolation material is filled. If the STI stress cannot be reduced or eliminated, the silicon wafer cannot be restored to flatness. With this stress effect induced through the STI fabrication process, the saturation current of the fabricated NMOS and PMOS devices may drop by as much as 15% as the channel narrows, resulting in the dependency of the saturation current of the MOS devices on the channel width, which may negatively affect the driving capability of the devices.

### SUMMARY

The present disclosure provides a method for fabricating an MOS device, the method may include: depositing a silicon-nitride (SiN) layer above a substrate surface of a silicon wafer; etching one or more trenches on the silicon wafer; performing a high-temperature post-liner-anneal process on the silicon wafer to reduce stress from the etched SiN layer to the silicon wafer; and filling the one or more trenches with oxide isolation material. The high-temperature post-liner-anneal process may reduce the dependence of the saturation current of the MOS device on the channel width.

The present disclosure further provides a MOS device, the device includes one or more shallow trench isolations (STIs).

### BRIEF DESCRIPTION OF THE DRAWINGS

The foregoing and other features of the present disclosure will become more fully apparent from the following description and appended claims, taken in conjunction with the accompanying drawings. These drawings depict only several embodiments in accordance with the disclosure and are, therefore, not to be considered limiting of its scope. The disclosure will be described with additional specificity and detail through use of the accompanying drawings.

FIG. 1A shows a cross-sectional view of a semiconductor structure prepared for Sallow Trench Isolation (STI) fabrication;

FIG. 1B shows a cross-sectional view of a semiconductor structure after a first part of a trench-etching operation is partially performed during the STI fabrication process;

FIG. 2A shows a cross-sectional view of a semiconductor structure after a second part of the trench-etching operation is performed during the STI fabrication process;

FIG. 2B shows a cross-sectional view of a semiconductor structure after a liner layer operation;

FIG. 3A shows a cross-sectional view of a semiconductor structure after a post-liner-annealing operation;

FIG. 3B shows a cross-sectional view of a semiconductor structure after a trench-filing operation;

FIG. 4A shows a cross-sectional view of a semiconductor structure after a mechanical polishing operation;

FIG. 4B shows a cross-sectional view of a semiconductor structure after a SiN removal operation; and

FIG. 5 shows a flow diagram of an illustrative embodiment of a process for fabricating a MOS device illustrates an electronic chip device, all according to certain embodiments of the present disclosure.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here. It will be readily understood that the aspects of the present disclosure, as generally described herein, and illustrated in the Figures, can be arranged, substituted, combined, and designed in a wide variety of different configurations, all of which are explicitly contemplated and make part of this disclosure.

Throughout the disclosure, the term “semiconductor structure” may broadly refer to a physical structure constructed based on a semiconductor fabrication process. For example, a fabrication process may be a multiple-step sequence of photographic and chemical-processing operations. During the fabrication process, different electronic components may gradually be created on a semiconductor wafer using various depositions and etching operations. The fabrication process may deposit a layer of material on top of other materials, or etch/wash away material from the semiconductor structure. Throughout the disclosure, when a first layer of material is deposited “above” a second layer of material, the first layer of material may either be directly on the top of the second layer, or there might be additional material in between the first and the second layers. In other words, after the second layer of material is fabricated, additional material may be deposited on the top of the second layer before the first layer of material being deposited. Further, the term “top”, “bottom”, “above”, “below”, “up”, or “down” may be relative to one surface of a horizontally-placed silicon wafer.

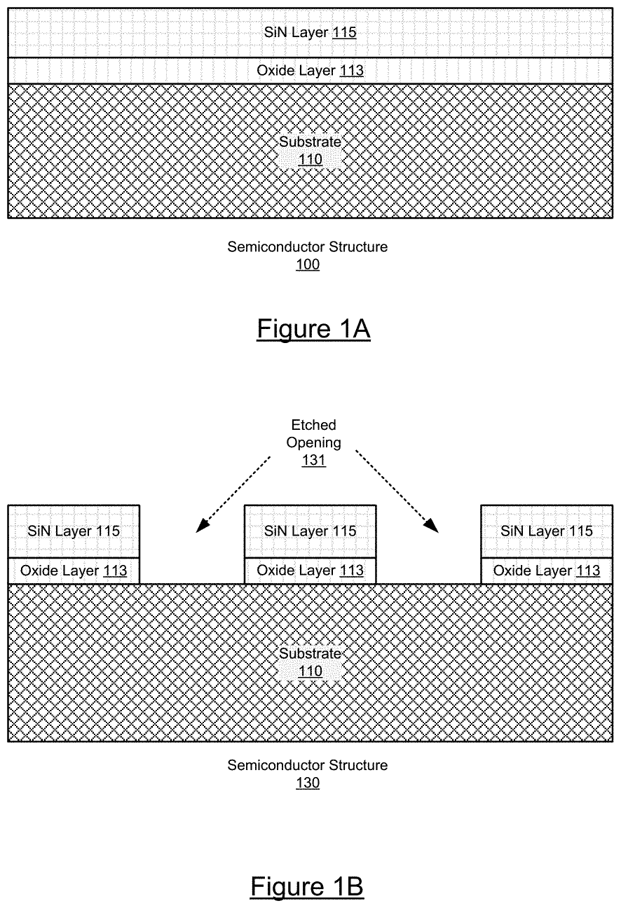

FIG. 1A shows a cross-sectional view of a semiconductor structure prepared for Sallow Trench Isolation (STI) fabrication. In FIG. 1A, a semiconductor structure 100 may show a section of a silicon wafer after going through a pre-STI fabrication operation. Specifically, the part of the silicon wafer that supports the multiple layers of material may be referred to as a substrate 110. The pre-STI fabrication operation may construct multiple layers of material on a surface of the substrate 110 (i.e. top surface). Thus, after the pre-STI fabrication operation, the substrate 110 may have a pad oxide layer 113 formed/grown/deposited on its top surface and a pad silicon nitride (SiN) layer 115 formed above the pad oxide layer 113.

In some embodiments, the pad oxide layer 113 may be formed by placing the semiconductor structure 100 through an oxidize operation at a temperature of about 850 to 1000° C. The pad oxide layer 113, which may have a thickness between about 50 and 300 Angstroms, may provide foundational support to the pad SiN layer 115. Afterward, the pad SiN layer 115 may be deposited above the pad oxide layer 113 through a chemical vapor deposition operation. The pad SiN layer 115 may have a thickness of about 1000 to 2000 angstroms.

FIG. 1B shows a cross-sectional view of a semiconductor structure after a first part of a trench-etching operation is partially performed during the STI fabrication process. Specifically, the semiconductor structure 130 in FIG. 1B shows the outcome of a trench-etching photolithography operation performed on the semiconductor structure 100 of FIG. 1A. During the photolithography operation, a photoresist pattern (not shown in FIG. 1A or FIG. 1B) may be formed above the pad SiN layer 115. Afterward, the pad SiN layer 115 and the oxide layer 113 that are not covered by the photoresist pattern may be etched away, exposing portions of the upper surface of the semiconductor substrate 110 which were previously covered by the oxide layer 113 and the pad SiN layer 115. Once the trench-etching operation is completed, the photoresist pattern on the top of the pad SiN layer 115 may be stripped/removed, and the semiconductor structure 130 may show multiple etched openings 131.

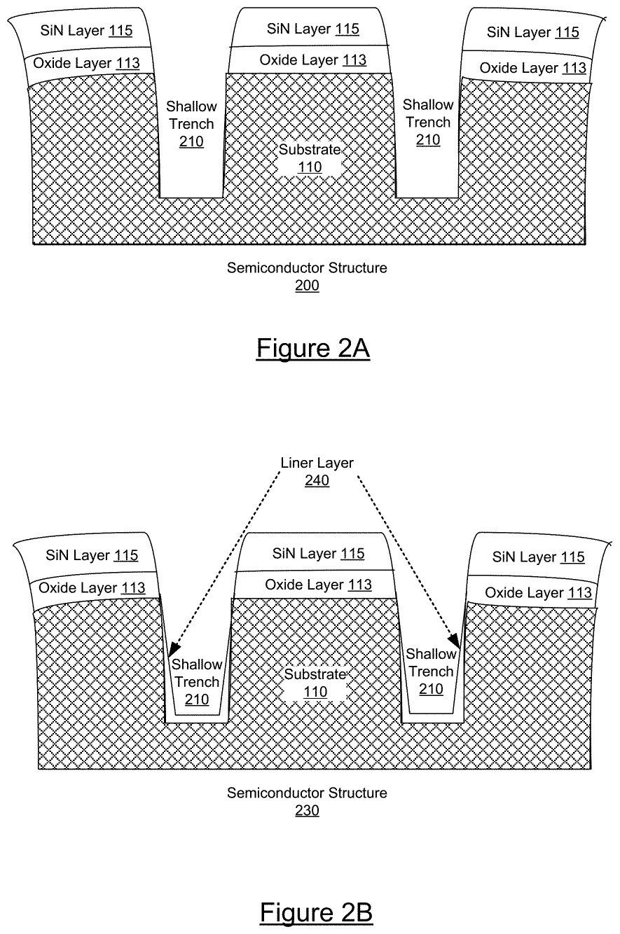

FIG. 2A shows a cross-sectional view of a semiconductor structure after a second part of the trench-etching operation is performed during the STI fabrication process. The trench-etching operation may be performed based on the semiconductor structure 130 of FIG. 1B, resulting one or more shallow trenches 210 as shown in the semiconductor structure 200 of FIG. 2A. Specifically, the trench-etching operation may utilize a dry-etching or a wet-etching process (e.g., applying a reactive gas through the etched openings 131 of the FIG. 1B) to create the shallow trenches 210 that extend through the etched openings 131 and further into the substrate 110. The etched shallow trenches 210 may have a depth of about 3000 to 5000 angstroms.

In some embodiments, during the above trench-etching operation, mechanical stress may be introduced in the semiconductor substrate 200 near the shallow trenches 210. Specifically, during the pre-STI fabrication operation, when the pad (SiN) layer 115 is deposited on the top surface of the silicon wafer, the bottom surface of the silicon wafer may also be deposited with similar materials at the same time. Although the pad SiN layer 115 may generate internal stress, the stresses from the SiN material on both sides of the wafer may cancel each other out, resulting the wafer to remain flat.

In the subsequent trench-etching operation, the pad SiN layer 115 on the top surface of the wafer may be etched to have“islands” and “valleys”, and the SiN layer on the bottom surface of the wafer remains intact. This may cause the stresses applied to the top and bottom surface of the wafer to be in-balanced. As shown in FIG. 2A, the center of the silicon wafer may bulge upward, and the volumes of the trenches may be enlarged. As a result, the semiconductor structure 200 may become curved due to the stress generated during this operation. These stresses may be difficult to eliminate and the silicon wafer may be difficult to be restored to flatness. Subsequently, more dielectric material may be filled into the trenches, and the silicon wafer may be subject to more stresses due to the excess dielectric material.

FIG. 2B shows a cross-sectional view of a semiconductor structure after a liner layer operation. The liner layer operation may be performed based on the semiconductor structure 200 of FIG. 2A, resulting a liner layer 240 formed on external surfaces of the shallow trenches 210, as shown by the semiconductor structure 230 of FIG. 2B. The liner layer 240 may be formed by depositing silicon oxide in the shallow trenches 210 via a chemical vapor deposition mechanism.

In some embodiments, after the depositing of the liner layer 240, the semiconductor structure 230 may undergo an active reverse-etching operation. Specifically, the reverse-etching operation may remove/etch-down the liner layer 240 to be lower than the top of the substrate 110 surface, so that the liner layer 240 may not cover the SiN layer 115 and/or the oxide layer 113.

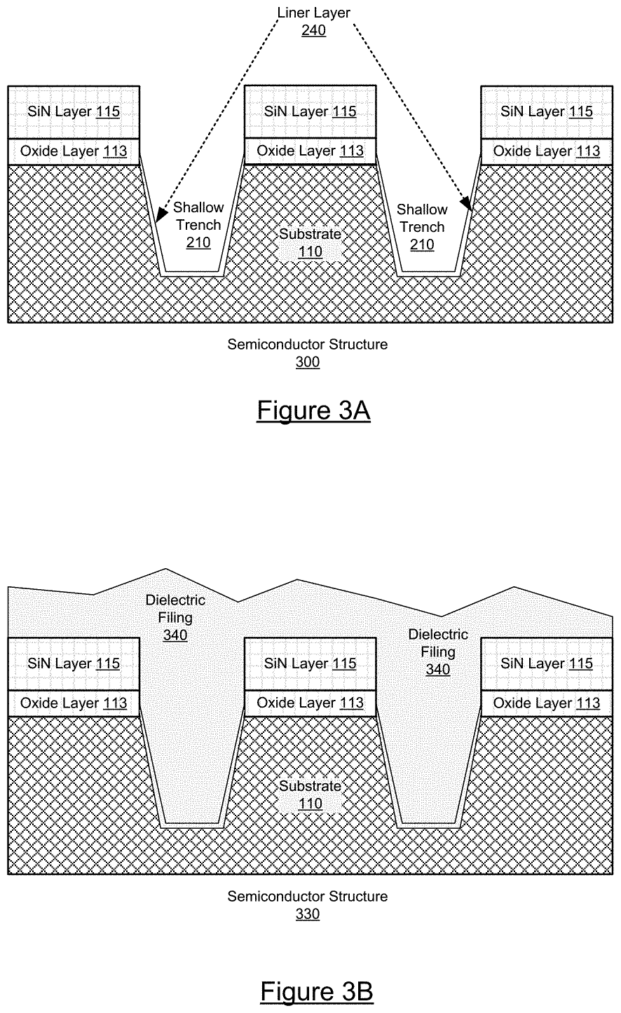

FIG. 3A shows a cross-sectional view of a semiconductor structure after a post-liner-annealing operation. The post-liner-annealing operation may be performed after the depositing of the liner layer as shown by the semiconductor structure 230 of FIG. 2B. The purpose of this post-liner-annealing operation is to reduce or remove stresses in the semiconductor structures 200 and 230, which were caused by etching of the shallow trenches 210. The result of the post-liner-annealing operation may be shown in the semiconductor structure 300 of FIG. 3A, in which the stresses that caused the curving of the semiconductor structure 200 may be reduced/removed, and the semiconductor structure 230 is substantially flattened.

In some embodiments, the post-liner-annealing operation may place the semiconductor structure 230 of FIG. 2B in an annealing equipment at a temperature of above 1150° C. (preferably above 1200° C.) for at least 30 minutes. After this annealing operation, the semiconductor structure 300 may be cooled down for the subsequent operations.

FIG. 3B shows a cross-sectional view of a semiconductor structure after a trench-filing operation. During the trench-filing operation, a dielectric oxide filing 340 may be deposited on the semiconductor structure 300 of FIG. 3A, to fill the shallow trenches 210 and cover the top surface of the semiconductor structure 300. The outcome of the trench-filing operation may be shown in the semiconductor structure 330 of FIG. 3B. Since during the post-liner-annealing operation, the semiconductor structure 330 has substantially reduced/eliminated the curves and unevenness on the wafer surface. As a result, the dielectric oxide filing 340 will not squeeze any of the active regions, thereby reducing the dependence of the saturation current of the MOS device on the channel width.

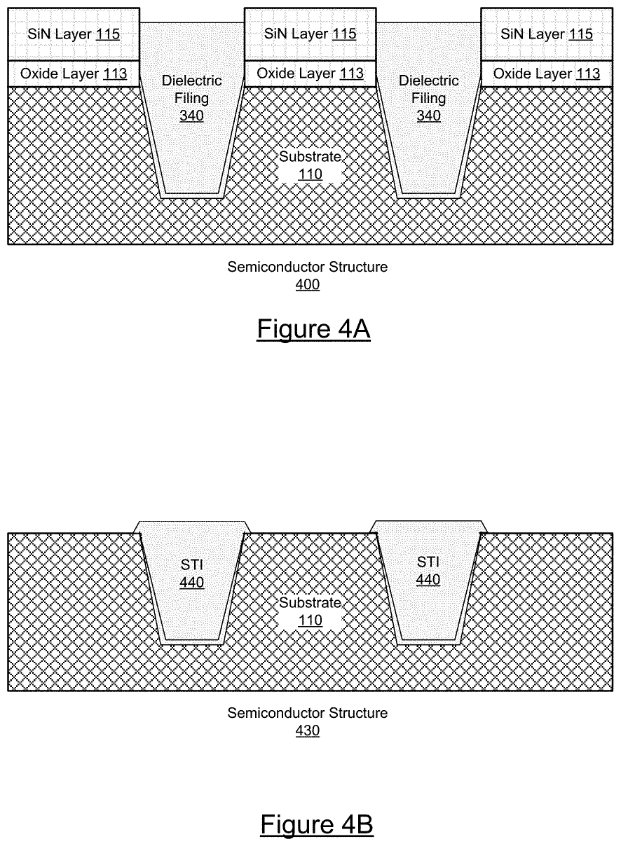

FIG. 4A shows a cross-sectional view of a semiconductor structure after a mechanical polishing operation. The mechanical polishing operation may be performed based on the semiconductor structure 330 of FIG. 3B. Specifically, the mechanical polishing operation may be a chemical mechanical polishing (CMP) operation for planarization and to remove the excess dielectric filing 340 until the pad SiN layer 115 is exposed on the upper surface of structure, as shown by semiconductor structure 400 of FIG. 4A.

FIG. 4B shows a cross-sectional view of a semiconductor structure after a SiN removal operation. The SiN removal operation may be performed based on the semiconductor structure 400 of FIG. 4A. During the SiN removal operation, a mechanical polishing or an acid washing operation may remove the pad SiN layer 115 and the pad Oxide Layer 113 from the top surface of the structure, and the outcome of which may be shown in the semiconductor structure 430 of FIG. 4B. The removal operation may stop once the surface of the substrate 110 is exposed. Afterward, STI 440 may be deemed formed in the semiconductor structure 430.

In some embodiments, a semiconductor fabrication system may be configured to perform some or all of the above fabrication operations and to construct one or more STIs in a wafer. The semiconductor fabrication system may include, without limitation, oxidation equipment, deposition equipment, lithographic equipment, cleaning equipment, annealing equipment, and dicing equipment. A wafer, which may be a thin slice of semiconductor material (e.g., silicon crystal), may be processed by equipment from the above system one or more times based on operation routes, product's specifications, and manufacturing recipes.

In some embodiments, the oxidization equipment may be configured to perform one or more of thermal oxidation, wet anodization, chemical vapor deposition (CVD), and/or plasma anodization or oxidation operations. The oxidation equipment may be configured to oxidize the surface of the wafer in order to form a layer of silicon dioxide. The deposition equipment may be configured to deposit a layer of specific material over the wafer. In some embodiments, the deposition equipment may deposit an oxide layer or a SiN layer above a surface of the wafer.

In some embodiments, the lithographic equipment may be configured to perform wet-etching, dry-etching, or plasma-etching operations in order to construct and/or remove portions of semiconductor layers. The cleaning equipment may be configured to rinse and clean the surface of semiconductor components after the deposition, etching, and/or dicing operations. The annealing equipment may be configured to anneal the semiconductor components by applying high-temperature heat toward the wafer. The dicing equipment may be configured to dice a fabricated silicon wafer into a diced wafer. Afterward, the silicon wafer may be cut/diced into a plurality of wafer segments, each of which may be used to construct a finished product. The wafer segments may then be packaged into a final product.

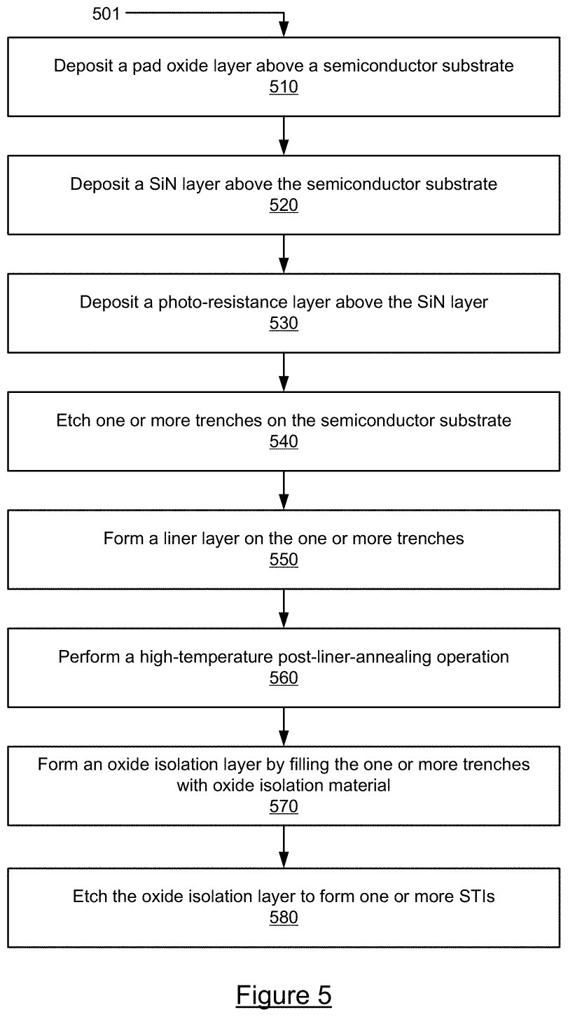

FIG. 5 shows a flow diagram of an illustrative embodiment of a process 501 for fabricating a MOS device. The process 501 sets forth various functional blocks or actions that may be described as processing steps, functional operations, events, and/or acts, which may be performed by hardware, software, and/or firmware. Those skilled in the art in light of the present disclosure will recognize that numerous alternatives to the functional blocks shown in FIG. 5 may be practiced in various implementations.

One skilled in the art will appreciate that, for this and other processes and methods disclosed herein, the functions performed in the processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments. Moreover, one or more of the outlined steps and operations may be performed in parallel.

At block 510, during a STI fabrication process, a pad oxide layer may be deposited above a substrate surface of a silicon wafer. At block 520, a SiN layer may be deposited above the pad oxide layer. Alternatively, the SiN layer may be deposited directly above the substrate surface of the silicon wafer without the pad oxide layer. Such an approach may reduce the process complexity and manufacturing cost.

At block 530, a photo-resistance layer may be deposited above the SiN layer. At block 540, a lithographic operation may etch one or more trenches on the silicon wafer. Specifically, the lithographic operation may etch through the photo-resistance layer to define the one or more trenches. Afterward, an etching operation may etch through the SiN layer and the substrate surface to form the one or more trenches.

At block 550, a liner layer may be formed on interior surfaces of the one or more trenches. At block 560, the fabrication process may perform a high-temperature post-liner-anneal operation on the silicon wafer to reduce stress from the etched SiN layer to the silicon wafer. Specifically, the high-temperature post-liner-anneal operation may be performed at a temperature of above 1,150 degrees Celsius for at least about 30 minutes. The post-liner-anneal operation may reduce stresses in the semiconductor substrate near the one or more trenches, thereby improving semiconductor device performance.

At block 570, the fabrication process may fill the one or more trenches with oxide isolation material. Specifically, dialectic oxide isolation material may be deposited to form an oxide isolation layer that fills the one or more trenches and covers the SiN layer. At block 580, the fabrication process may etch the oxide isolation layer until the top of the substrate surface is exposed to form one or more shallow trench isolations (STIs). The fabrication process may etch down the oxide isolation layer, the photo-resistance layer, the SiN layer, and the oxide isolation layer until reaching the top of the substrate surface to form the one or more STIs. In some embodiments, the etching of the oxide isolation layer may use a dry-etching operation or a wet-etching operation. The constructed STIs may be used in a Metal-Oxide Semiconductor (MOS) device.

Thus, multiple embodiments of a method for fabricating the MOS device have been described. Although the present disclosure has been described with reference to specific exemplary embodiments, it will be recognized that the disclosure is not limited to the embodiments described, but can be practiced with modification and alteration within the spirit and scope of the appended claims. Accordingly, the specification and drawings are to be regarded in an illustrative sense rather than a restrictive sense.

One skilled in the art will appreciate that, for this and other apparatuses and methods disclosed herein, the functions performed in the processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments. Moreover, one or more of the outlined steps and operations may be performed in parallel.

We claim:

1. A method for fabricating a Metal-Oxide Semiconductor (MOS) device, comprising:
depositing a silicon-nitride (SiN) layer above a substrate surface of a silicon wafer;
etching one or more trenches on the silicon wafer;
performing a high-temperature post-liner-anneal operation on the silicon wafer to reduce stress from the etched SiN layer to the silicon wafer; and
filling the one or more trenches with oxide isolation material.

2. The method as recited in claim 1, further comprising:
prior to the depositing of the SiN layer, depositing a pad oxide layer above the substrate surface of the silicon wafer, wherein the SiN layer is deposited above the pad oxide layer.

3. The method as recited in claim 1, further comprising:
after the depositing of the SiN layer, depositing a photo-resistance layer above the SiN layer.

4. The method as recited in claim 3, wherein the etching of the one or more trenches comprises:
performing a lithographic operation through the photo-resistance layer to define the one or more trenches; and
performing an etching operation through the SiN layer and the substrate surface to form the one or more trenches.

5. The method as recited in claim 1, further comprising:
after the etching of the one or more trenches and prior to the performing of the high-temperature post-liner-anneal operation, growing a liner layer on interior surfaces of the one or more trenches.

6. The method as recited in claim 3, wherein the filling of the one or more trenches comprises:
depositing the oxide isolation material to form an oxide isolation layer that fills the one or more trenches and covers the SiN layer.

7. The method as recited in claim 6, further comprising:
etching the oxide isolation layer to the top of the substrate surface to form one or more shallow trench isolations (STIs).

8. The method as recited in claim 7, wherein the etching of the oxide isolation layer uses a dry-etching or a wet-etching process.

9. The method as recited in claim 1, wherein the high-temperature post-liner-anneal operation is performed at a temperature of above 1,150 degrees Celsius for at least about 30 minutes.

10. A method for fabricating a Metal-Oxide Semiconductor (MOS) device, comprising:
depositing a pad oxide layer above a substrate surface of a silicon wafer;
depositing a silicon-nitride (SiN) layer above the pad oxide layer;
depositing a photo-resistance layer above the SiN layer;
etching one or more trenches through the photo-resistance layer, the SiN layer, and the pad oxide layer;
performing a high-temperature post-liner-anneal operation to flatten curviness of the silicon wafer caused by the SiN layer;
depositing an oxide isolation layer to fill the one or more trenches; and
etching down the oxide isolation layer, the photo-resistance layer, the SiN layer, and the oxide isolation layer until reaching the top of the substrate surface to form one or more shallow trench isolations (STIs).

11. The method as recited in claim 10, further comprising:
prior to the etching of the one or more trenches, performing a lithographic operation to define the one or more trenches through the photo-resistance layer.

12. The method as recited in claim 10, further comprising:
after the etching of the one or more trenches and prior to the performing of the high-temperature post-liner-anneal operation, growing a liner layer on interior surfaces of the one or more trenches.

13. The method as recited in claim 10, wherein the depositing of the oxide isolation layer further comprises:
forming the oxide isolation layer by depositing oxide isolation material to fill the one or more trenches and cover the photo-resistance layer.

14. The method as recited in claim 10, wherein the high-temperature post-liner-anneal process is performed at a temperature of above 1,150 degrees Celsius for at least about 30 minutes.

15. The method as recited in claim 10, wherein the curviness of the silicon wafer is caused by stress from a second SiN layer formed on the other surface of the silicon wafer.

16. A Metal-Oxide Semiconductor (MOS) device, comprising one or more shallow trench isolations (STIs), wherein the one or more STIs is constructed by:
depositing a silicon-nitride (SiN) layer above a substrate surface of a silicon wafer;
etching one or more trenches on the silicon wafer,
performing a high-temperature post-liner-anneal operation on the silicon wafer to reduce stress from the etched SiN layer to the silicon wafer, and filling the one or more trenches with oxide isolation material.

17. The MOS device as recited in claim 16, wherein the one or more STIs is further constructed by:
after the depositing of the SiN layer, depositing a photo-resistance layer above the SiN layer; and
after the filling of the one or more trenches, etching the oxide isolation material until the top of the substrate surface is exposed to form the one or more STIs.

18. The MOS device as recited in claim 17, wherein the etching of the one or more trenches comprises:
performing a lithographic process through the photo-resistance layer to define the one or more trenches; and
performing an etching process through the SiN layer and the substrate surface to form the one or more trenches.

19. The MOS device as recited in claim 16, wherein the one or more STIs is further constructed by:
after the etching of the one or more trenches and prior to the performing of the high-temperature post-liner-anneal operation, growing a liner layer on interior surfaces of the one or more trenches.

20. The MOS device as recited in claim 16, wherein the high-temperature post-liner-anneal operation is performed at a temperature of above 1,150 degrees Celsius for at least about 30 minutes.
